(19) United States
(12) Patent Application Publication
(10) Pub. No.: US 2025/0273537 A1
(43) Pub. Date: Aug. 28, 2025

(54) POSITIONING DEVICE WITH HEAT DISSIPATION EFFECT

(71) Applicant: HANWIT PRECISION INDUSTRIES LTD., New Taipei (TW)

(72) Inventors: Ying-Chih TSENG, New Taipei (TW); Ming-De WU, New Taipei (TW); Ching-Kai CHANG, New Taipei (TW)

(21) Appl. No.: 18/584,294

(22) Filed: Feb. 22, 2024

(51) Int. Cl. H01L 23/40

(52) U.S. Cl. CPC H01L 23/4006; H01L 2023/4087

(57) ABSTRACT

A positioning device with heat dissipation effect, includes a limiting mechanism including a sleeve and an adjusting device located inside the sleeve, and a base set at the bottom side of the sleeve. The sleeve has an accommodating space for assembling the adjusting device and is provided with a non-planar heat dissipation portion. The adjusting device includes a coupling member having a connecting part and an operating part, and an elastic member sleeved on the coupling member. The base has a docking portion, and a connecting portion on one side of the docking portion for the connecting part to be assembled at the connecting portion. A first board member can be assembled at the docking portion of the base and a second board member can be assembled at the bottom of the sleeve, so that the sleeve can assist the second board member in dissipating heat.

### BACKGROUND OF THE INVENTION

### 1. Field of the Invention

The invention provides a positioning device with heat dissipation effect, especially a positioning device that can assist preset board members and heating elements on the preset board members to dissipate heat. In the positioning device, the sleeve, coupling member and elastic member of the limiting mechanism assembled on the base can be combined to assemble the preset first and second board members to achieve the purpose of assisting the heat dissipation of the preset board members and the heating element on the preset board members.

### 2. Description of the Related Art

With the vigorous development of industrial technology, various industrial products such as computers, televisions, telephones, refrigerators, washing machines, wardrobes, drawers or desks have long become indispensable items in people's lives. Most of the aforementioned industrial products are assembled from multiple components, such as the casing of a computer host, the circuit board inside the TV casing and its heat sink, the desktop board and supporting side panels of a desk, or board-to-board assembly between two opposing circuit boards, etc. Most of the components are assembled with each other through screw locking, so that the industrial products can be disassembled into multiple components to facilitate transportation. Later, the assembled industrial products can also be partially disassembled for repair or replacement.

When used in the casing of the computer host, the circuit board inside the TV casing and its heat sink, or the board-to-board assembly between two opposing circuit boards, the heating elements of various electronic components (for example: central processing unit (CPU), microprocessor or chip, etc.) installed relative to circuit boards that match the circuit board of the computer host, the circuit board inside the TV casing, or the board-to-board assembly between two opposing circuit boards must be mounted with a heat dissipation device to assist the heating elements to dissipate heat. The heat dissipation device assembled at the heating element can also be locked and fixed to the circuit board around the heating element through screws. However, there must be a space for the locking screws around the heat dissipation device. If the heat dissipation cannot be assisted, the heat dissipation effect of the heat dissipation device will be affected, and it will also cause trouble during the production of the heat dissipation device.

Furthermore, since the various components of the aforementioned industrial products or circuit boards are assembled and combined with each other through screw locking, when each component is assembled, the surface of the component is often pressed by the heads of the screws. Over-tightening of the screws may cause damage such as denting or chipping. In order to solve the aforementioned problem of component damage caused by screw locking, some manufacturers also use welding and fixation to assemble the components. However, this design will make it difficult to disassemble some components of the industrial products after assembly, thereby making it difficult to repair or replace components.

Therefore, how to solve the current problems that when locking with screws, it is easy to cause the board to be damaged and difficult to disassemble, and the assembly on the board will affect the structure and poor performance of the board, that is the direction that relevant manufacturers in this industry are eager to study and improve.

### SUMMARY OF THE INVENTION

Therefore, in view of the above-mentioned problems and deficiencies, the inventor collected relevant information, and after many evaluations and considerations, he designed the invention of this positioning device with heat dissipation effect.

It is the main object of the present invention to provide a positioning device with heat dissipation effect, which comprises a limiting mechanism and a base. The limiting mechanism comprises a sleeve, and an adjusting device located inside the sleeve. The sleeve comprises an accommodating space defined therein for assembling the adjusting device, and a non-planar heat dissipation portion located on the outer side thereof. The adjusting device comprises a coupling member, and an elastic member sleeved on the coupling member. The coupling member comprises a connecting part located on one side thereof, and an operating part located on an opposite side thereof. The base is set at the bottom side of the sleeve, comprising a docking portion, a connecting portion on one side of the docking portion for the connecting part to be assembled at the connecting portion. The docking portion of the base can be assembled at a first positioning hole of a preset first board member, and the bottom of the sleeve can be assembled at a second positioning hole of a preset second board member. This facilitates the assembly or disassembly of the preset first board member and the preset second board member, and the sleeve of the limiting mechanism can be used to assist the preset second board member in heat dissipation.

It is another object of the present invention to provide a positioning device with heat dissipation effect, the sleeve of the limiting mechanism can be integrated with an external non-planar heat dissipation portion. The non-planar heat dissipation portion is selectively a plurality of fins formed on the outside of the sleeve in a two-phase symmetrical shape, a plurality of fins formed on the outside of the sleeve in a cross-shaped symmetry, a plurality of fins formed on the outside of the sleeve in a polygonal symmetry, a plurality of fins formed on the outside of the sleeve in a spiral shape, or a plurality of radial fins formed on the outside of the sleeve, and the sleeve is selectively made of aluminum, copper or alloy materials thereof, and the thermal conductivity of the sleeve is between 70˜500 W/m·k. Furthermore, the sleeve of the limiting mechanism comprises an inner cylinder and a heat dissipation cylinder covering the outside of the inner cylinder. And the non-planar heat dissipation portion is selectively a plurality of fins formed on the outside of the heat dissipation cylinder in a two-phase symmetrical shape, a plurality of fins formed on the outside of the heat dissipation cylinder in a cross-shaped symmetry, a plurality of fins formed on the outside of the heat dissipation cylinder in a polygonal symmetry, a plurality of fins formed on the outside of the heat dissipation cylinder in a spiral shape, or a plurality of radial fins formed on the outside of the heat dissipation cylinder. The inner cylinder and the heat dissipation cylinder are selectively made of aluminum, copper or alloy materials thereof, and the thermal conductivity of the inner cylinder and the heat dissipation cylinder being between 70˜500 W/m·k.

It is still another object of the present invention to provide a positioning device with heat dissipation effect, in which the limiting mechanism further comprises a stopper on the outside of the accommodating space of the sleeve to limit the coupling member located inside the accommodating space of the sleeve, so that the coupling member is movable vertically in the accommodating space, and the operating part on one side of the coupling member exposes the stopper; the stopper is arc-shaped and condenses inward to form a shrink mouth, which is used to limit the coupling member located inside the accommodating space of the sleeve; the coupling member comprises a flange portion protruding from the outside near the operating part to resist the inner edge surface of the shrink mouth of the stopper, a mounting portion located at an opposite outside of the accommodating space relative to the stopper for assembling a second board member, a through hole with a reduced diameter located on one side of the accommodating space near the mounting portion, and an inner shoulder formed at a position adjacent to the through hole and the accommodating space.

It is still another object of the present invention to provide a positioning device with heat dissipation effect, in which the operating part on one side of the coupling member of the limiting mechanism exposes the outer side of the stopper on one side of the accommodating space of the sleeve, and the operating part comprises a docking unit and an operating area, and the docking unit of the operating part is used for assembling at least a second positioning device; the said second positioning device comprises a second limiting mechanism, and the said second limiting mechanism comprises a second sleeve and a second adjusting device located inside the said second sleeve; the said second sleeve is provided with a second accommodating space for assembling the said second adjusting device inside, and is also provided with a second non-planar heat dissipation portion outside; the said second adjusting device comprises a second coupling member and a second elastic member attached onto the said second coupling member; the said second coupling member comprises a second connecting part on one side and a second operating part on an opposite side, and the said second operating part comprises a second docking unit and a second operating area, and the said second connecting part on one side of the said second coupling member is aligned and assembled at the docking unit of the operating area of the operating part, and the said second sleeve comprises an second mounting portion on one side that abuts the stopper.

It is still another object of the present invention to provide a positioning device with heat dissipation effect, in which the operating area of the operating part on one side of the coupling member and the said second operating area of the said second operating part of the said second coupling member are selectively in a star-shaped groove, a quadrangular groove, a hexagonal groove or a polygonal groove; the space between the outer stopper on one side of the accommodating space of the sleeve and the said second mounting portion of the said second sleeve is assembled with a third positioning hole of a third board member; the second board member is a heat dissipation device or a circuit board, the heat dissipation device of the second board member comprises a bottom plate resisting the surface of a predetermined heating element set on the first board member, and a plurality of heat dissipation fins formed on the surface of the bottom plate; the third board member is selectively a second heat dissipation device or a circuit board, and the second heat dissipation device of the third board member comprises a second bottom plate that resists the second board member, and a second plurality of heat dissipation fins formed on the surface of a second bottom plate.

It is still another object of the present invention to provide a positioning device with heat dissipation effect, in which the connecting portion on one side of the docking portion of the base is so arranged that the sleeve of the limiting mechanism is located axially outside the connecting portion; the base further comprises a chassis body; the docking portion that reduces the outer diameter is formed on the chassis body and the connecting portion that reduces the outer diameter is formed on the opposite side of the docking portion of the chassis body, and the preset first board member can be assembled at the docking portion; the connecting portion on one side of the base and the connecting part on one side of the coupling member of the limiting mechanism can be respectively a screw rod and a screw hole, a latch and a pin hole, or a tapered column and a tapered hole, which can be assembled or disassembled.

### BRIEF DESCRIPTION OF THE DRAWINGS

FIG. 1 is a three-dimensional appearance view of the first embodiment of the present invention.

FIG. 2 is a three-dimensional exploded view of the first embodiment of the present invention.

FIG. 3 is a three-dimensional exploded view of the first embodiment of the present invention from another angle.

FIG. 4 is a side cross-sectional exploded view of the first embodiment of the present invention.

FIG. 5 is a side cross-sectional view of the first embodiment of the present invention.

FIG. 6 is a three-dimensional appearance view of the application mode of the first embodiment of the present invention.

FIG. 7 is a three-dimensional appearance view (I) of the preferred embodiment of the sleeve of the present invention.

FIG. 8 is a three-dimensional appearance view (II) of the preferred embodiment of the sleeve of the present invention.

FIG. 9 is a three-dimensional appearance view (III) of the preferred embodiment of the sleeve of the present invention.

FIG. 10 is a three-dimensional appearance view (IV) of the preferred embodiment of the sleeve of the present invention.

FIG. 11 is a three-dimensional cross-sectional view of FIG. 10 of the present invention.

FIG. 12 is a three-dimensional exploded view of the second embodiment of the present invention.

FIG. 13 is a three-dimensional exploded view of the second embodiment of the present invention from another angle.

FIG. 14 is a side cross-sectional view of the second embodiment of the present invention.

FIG. 15 is a three-dimensional appearance view of the application mode of the third embodiment of the present invention.

FIG. 16 is a side cross-sectional view of the third embodiment of the present invention.

### DETAILED DESCRIPTION OF THE INVENTION

In order to achieve the above objects and effects, the technical means and structures adopted by the present invention are described in detail below with respect to the preferred embodiment of the present invention, so as to facilitate a complete understanding.

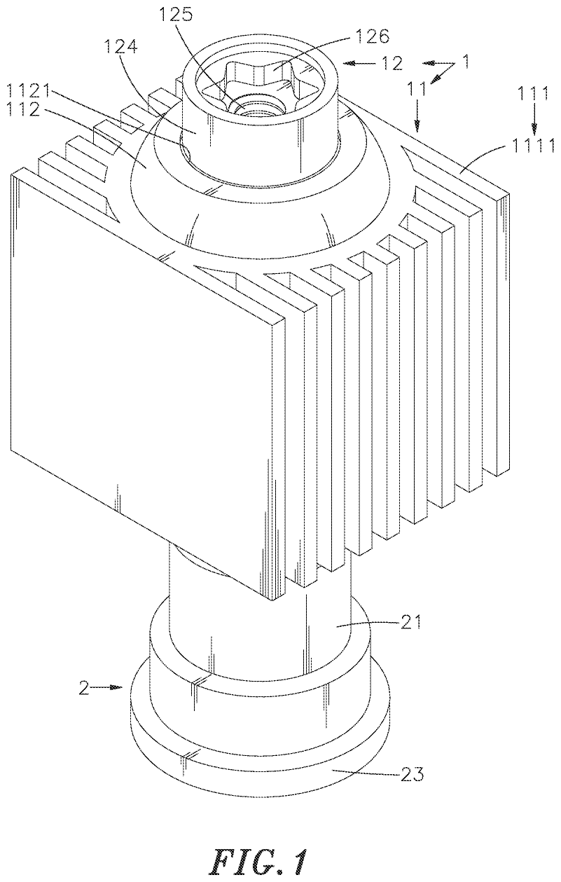

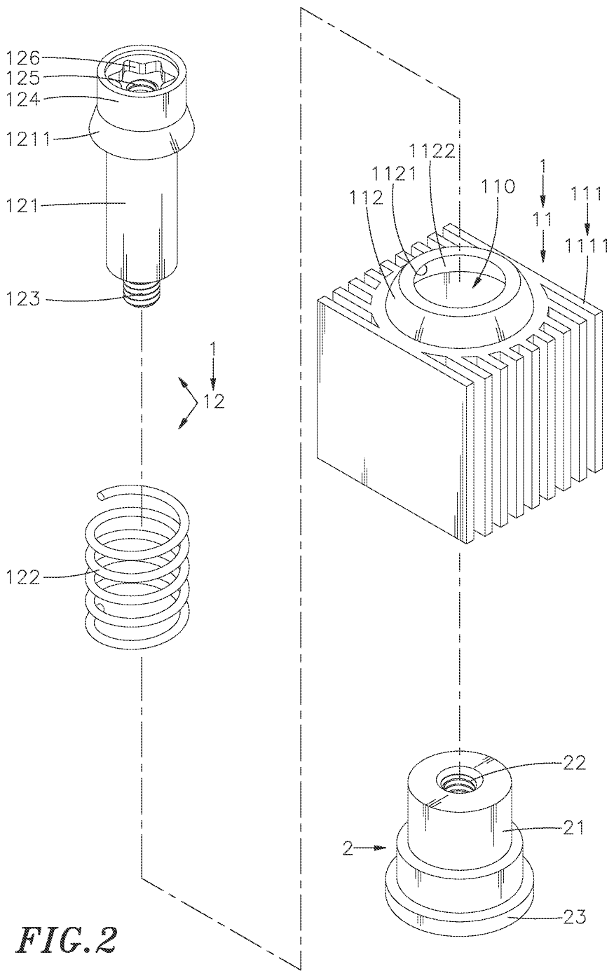

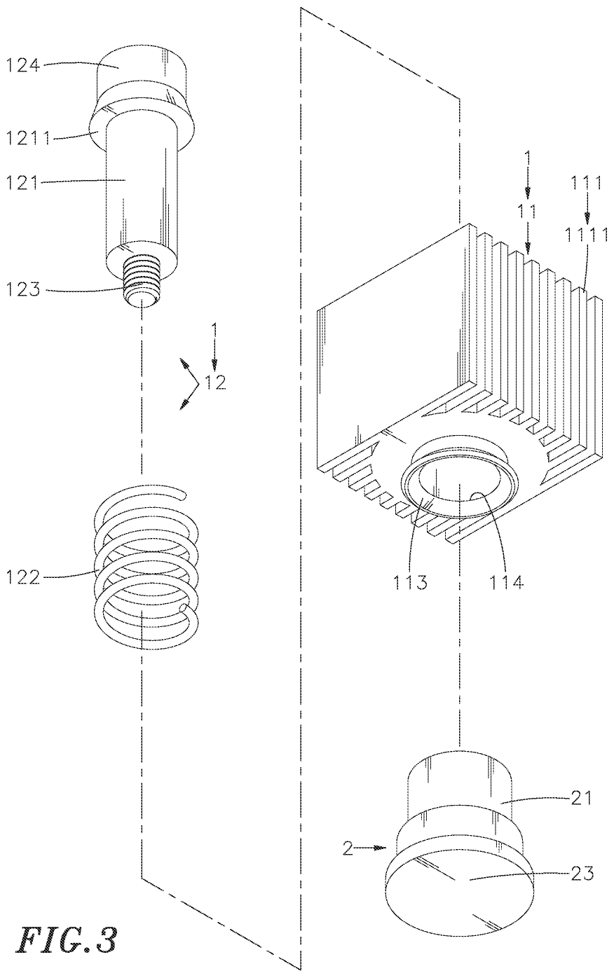

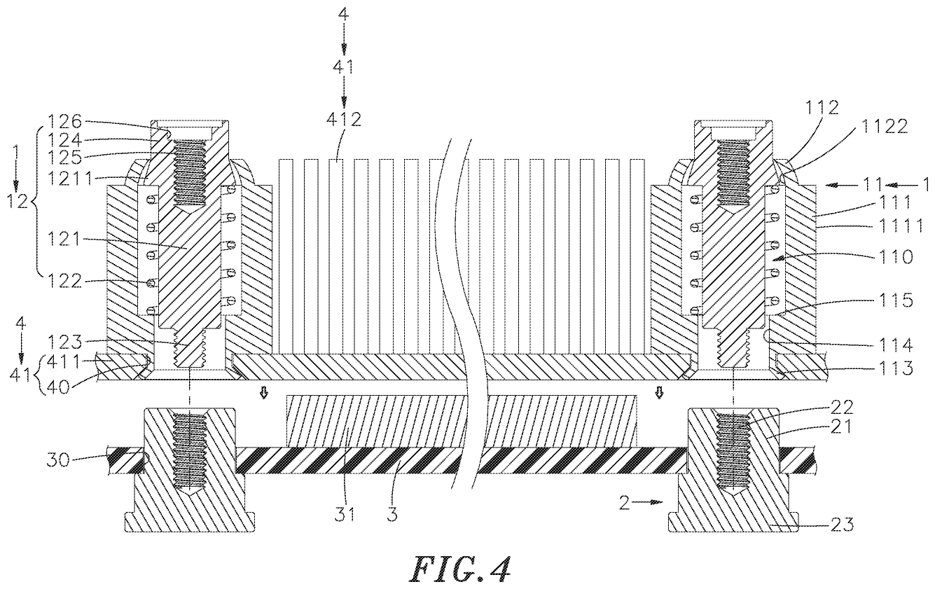

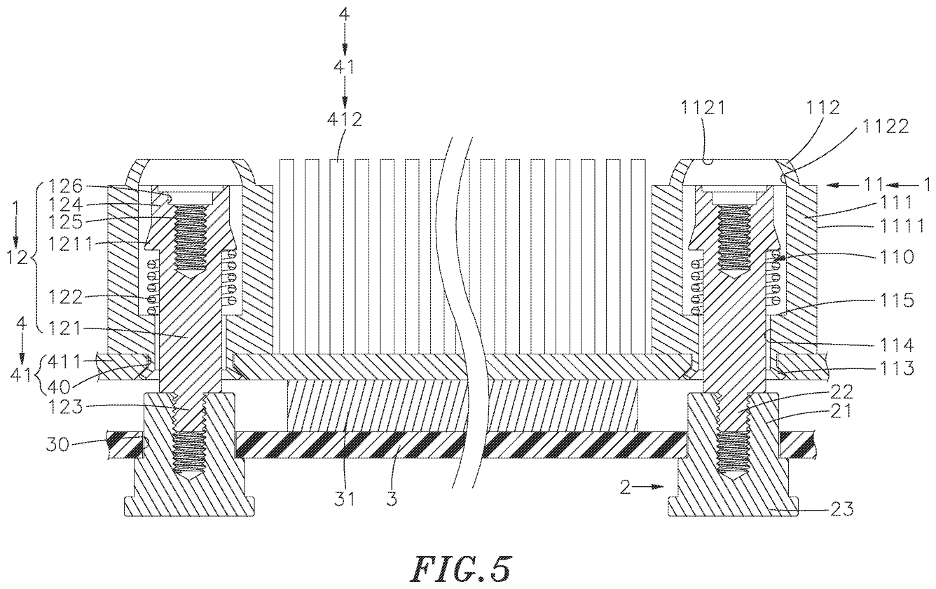

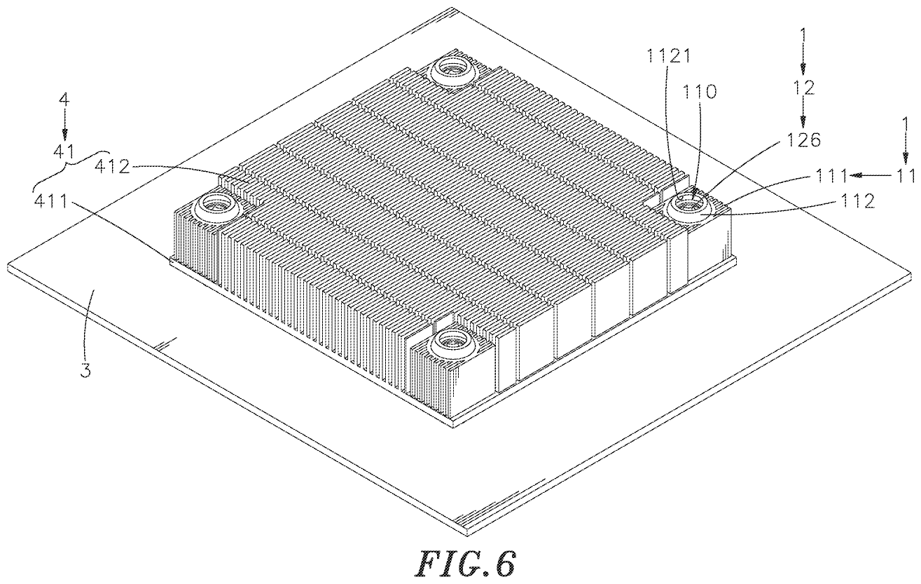

Please refer to FIGS. 1 to 11. It can be clearly seen from the figures that the positioning device with heat dissipation effect of the present invention comprises a limiting mechanism 1.

The limiting mechanism 1 comprises a sleeve 11 and an adjusting device 12 located inside the sleeve 11. The sleeve 11 is provided with an accommodating space 110 inside for assembling the adjusting device 12, and a non-planar heat dissipation portion 111 on the outside. The adjusting device 12 comprises a coupling member 121 and an elastic member 122 sleeved on the coupling member 121. The coupling member 121 is provided with a connecting part 123 on one side and an operating part 124 on the other side.

A base 2 can be set below the sleeve 11 of the limiting mechanism 1. The base 2 comprises a docking portion 21, a connecting portion 22 on one side of the docking portion 21 for the connecting part 123 to be aligned and assembled at the connecting portion 22, and a chassis body 23 on the other side of the docking portion 21. The docking portion 21 that reduces the outer diameter is formed on the chassis body 23, and the connecting portion 22 that reduces the outer diameter is formed on the other side of the docking portion 21 opposite the chassis body 23. The docking portion 21 can be used to assemble a first positioning hole 30 of a first board member 3.

The connecting part 123 on one side of the coupling member 121 of the limiting mechanism 1 of the present invention is assembled with the connecting portion 22 on one side of the base 2. The connecting part 123 and the connecting portion 22 can be respectively a screw rod and a screw hole, a latch and a pin hole, or a tapered column and a tapered hole, which can be assembled or disassembled.

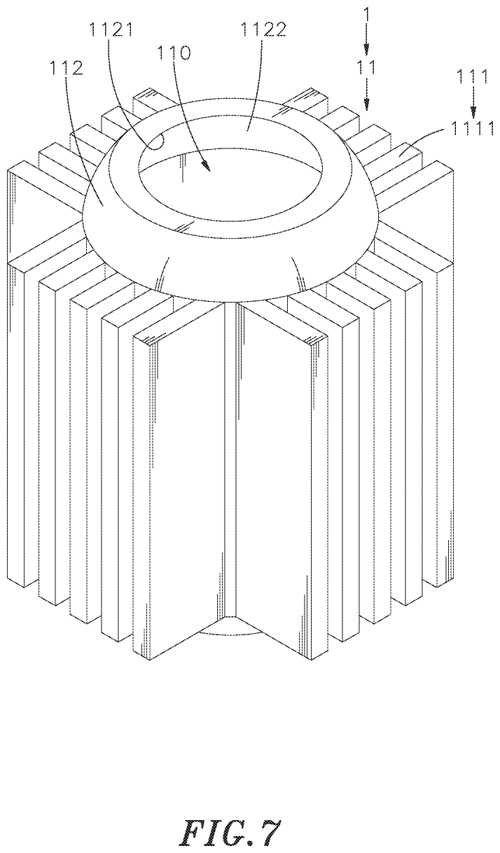

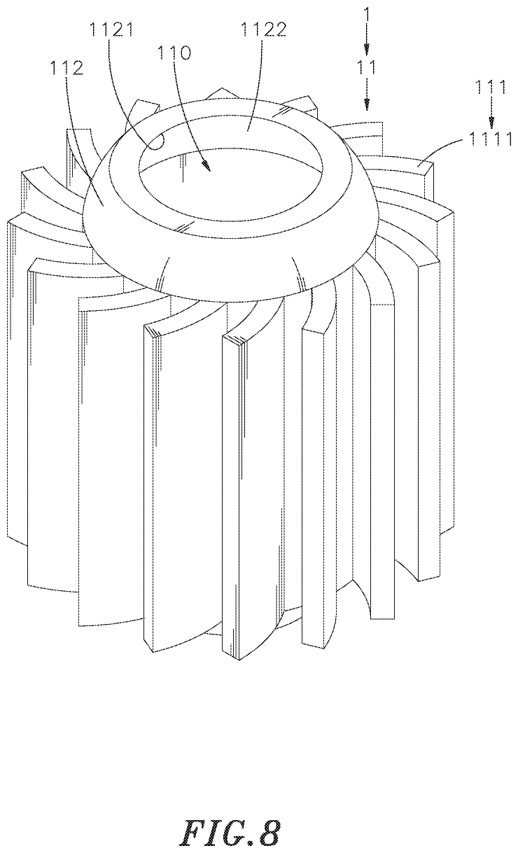

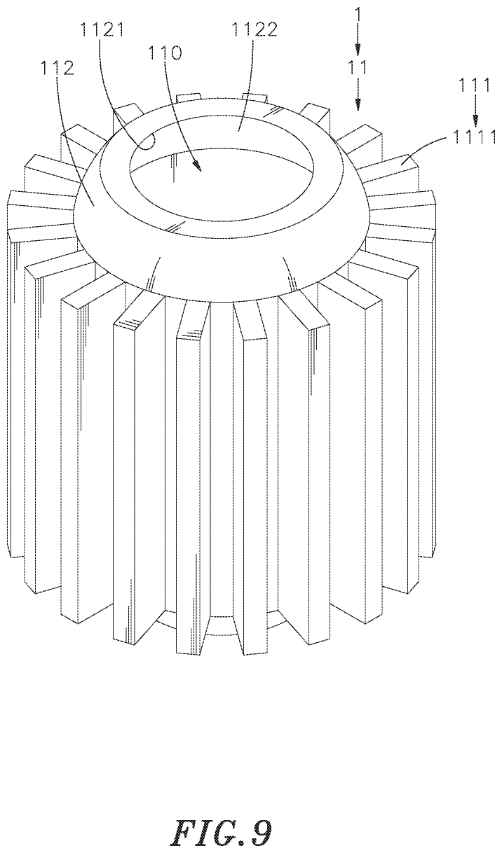

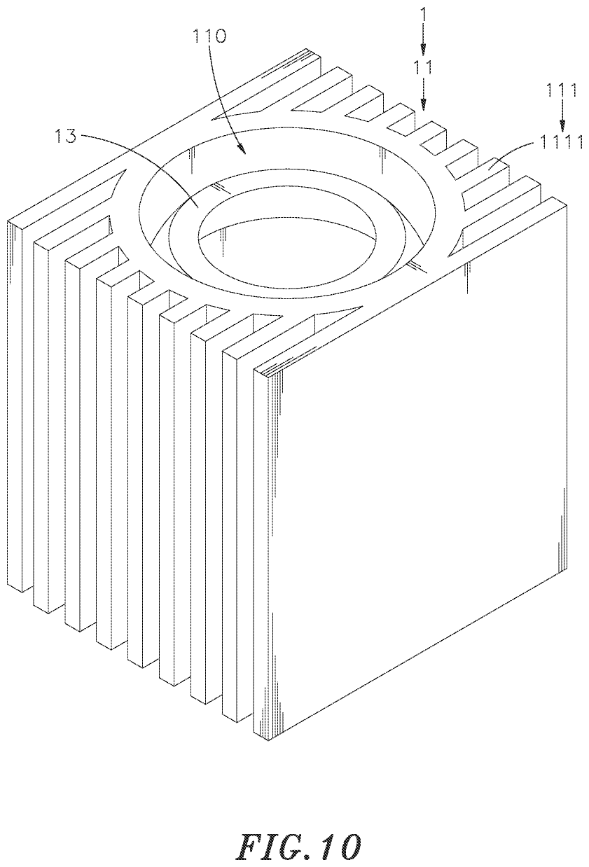

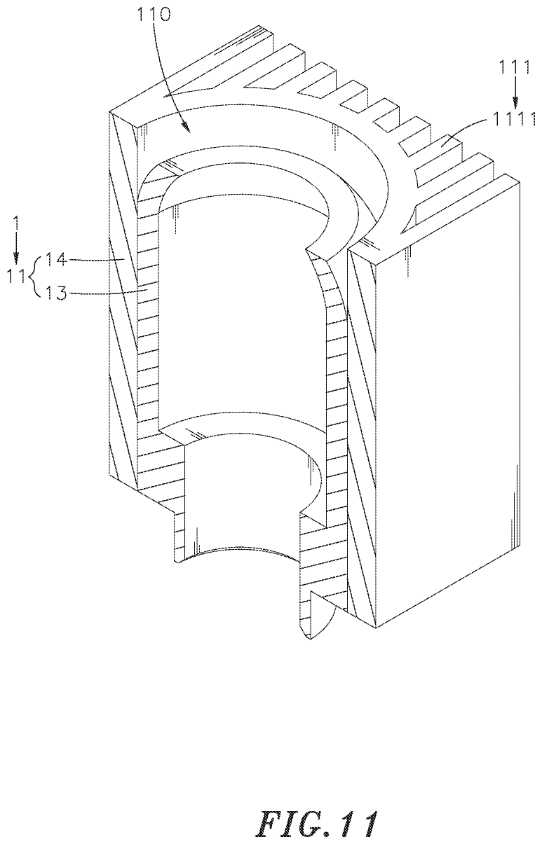

Furthermore, the sleeve 11 of the limiting mechanism 1 of the present invention can be integrated with the external non-planar heat dissipation portion 111. The heat dissipation portion 111 can be a plurality of fins 1111 formed on the outside of the sleeve 11 in a two-phase symmetrical shape (please also refer to FIGS. 1, 2, 3, and 6), a plurality of said fins 1111 formed on the outside of the sleeve 11 in a cross-shaped symmetry (please also refer to FIG. 7), a plurality of said fins 1111 formed on the outside of the sleeve 11 in a polygonal symmetry, a plurality of said fins 1111 formed on the outside of the sleeve 11 in a spiral shape (please also refer to FIG. 8), or a plurality of radial said fins 1111 formed on the outside of the sleeve 11 (please also refer to FIG. 9). The sleeve 11 can be made of aluminum, copper or alloy materials thereof. The thermal conductivity of the sleeve 11 can be between 70˜500 W/m·k. The sleeve 11 of the limiting mechanism 1 may comprise an inner cylinder 13 and a heat dissipation cylinder 14 covering the outside of the inner cylinder 13 (please also refer to FIGS. 10 and 11), and the non-planar heat dissipation portion 111 is formed on the outside of the heat dissipation cylinder 14. The heat dissipation portion 111 can be a plurality of said fins 1111 formed on the outside of the heat dissipation cylinder 14 in a two-phase symmetrical shape, a plurality of said fins 1111 formed on the outside of the heat dissipation cylinder 14 in a cross-shaped symmetry, a plurality of said fins 1111 formed on the outside of the heat dissipation cylinder 14 in a polygonal symmetry, a plurality of said fins 1111 formed on the outside of the heat dissipation cylinder 14 in a spiral shape, or a plurality of radial fins 1111 formed on the outside of the heat dissipation cylinder 14. The inner cylinder 13 and the heat dissipation cylinder 14 can be made of aluminum, copper or alloy materials respectively, and the thermal conductivity of the inner cylinder 13 and the heat dissipation cylinder 14 can be between 70˜500 W/m·k.

In addition, the limiting mechanism 1 of the present invention is provided with a stopper 112 on the outside of the accommodating space 110 of the sleeve 11. The stopper 112 is arc-shaped and condenses inward from the sleeve 11 to form a shrink mouth 1121. It is used to limit the coupling member 121 to be located inside the accommodating space 110 of the sleeve 11, so that the coupling member 121 can be located inside the accommodating space 110 and move vertically, and the operating part 124 on one side of the coupling member 121 can expose the shrink mouth 1121 of the stopper 112. The coupling member 121 comprises a flange portion 1211 protruding from the outside near the operating part 124, which can resist an inner edge surface 1122 of the shrink mouth 1121 of the stopper 112, a mounting portion 113 located at the other side of the accommodating space 110 relative to the stopper 112 for assembling a second positioning hole 40 of a second board member 4, a through hole 114 with a reduced diameter located on the side of the accommodating space 110 near the mounting portion 113, and an inner shoulder 115 formed at a position adjacent to the through hole 114 and the accommodating space 110.

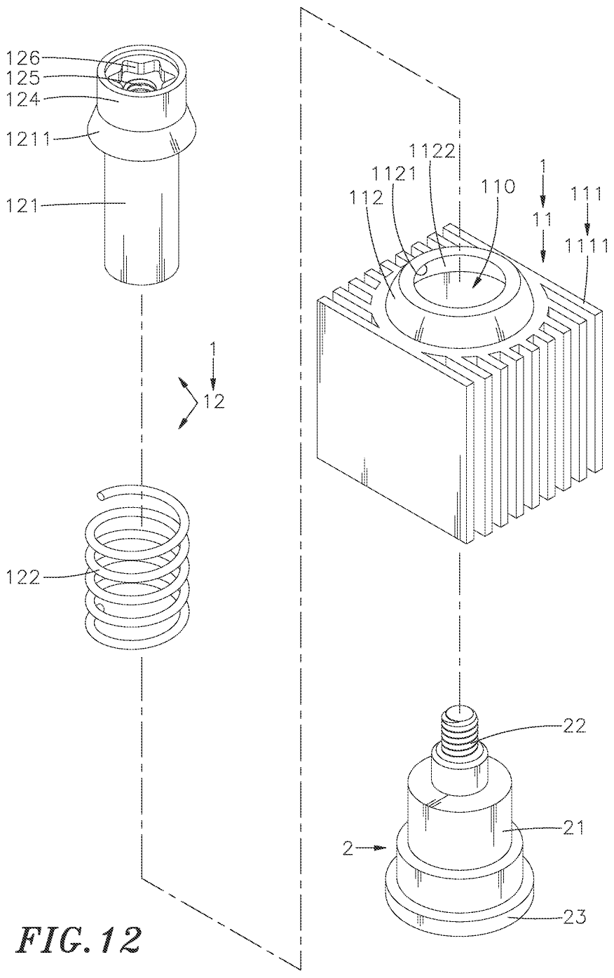

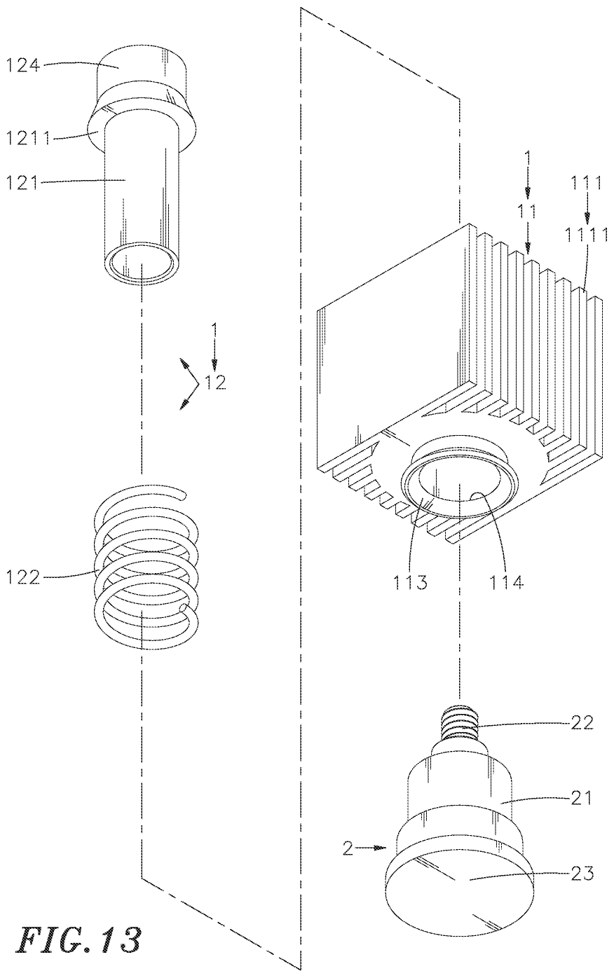

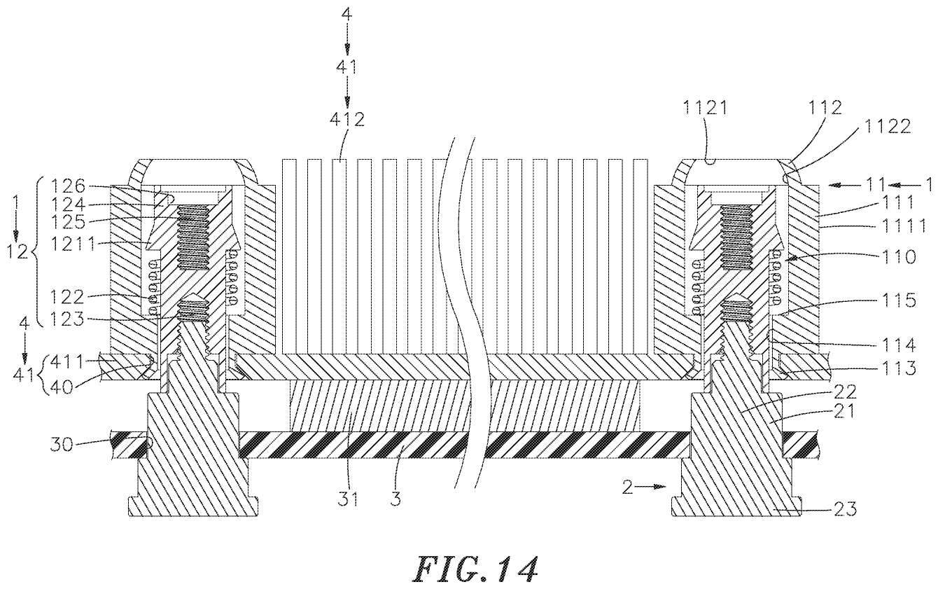

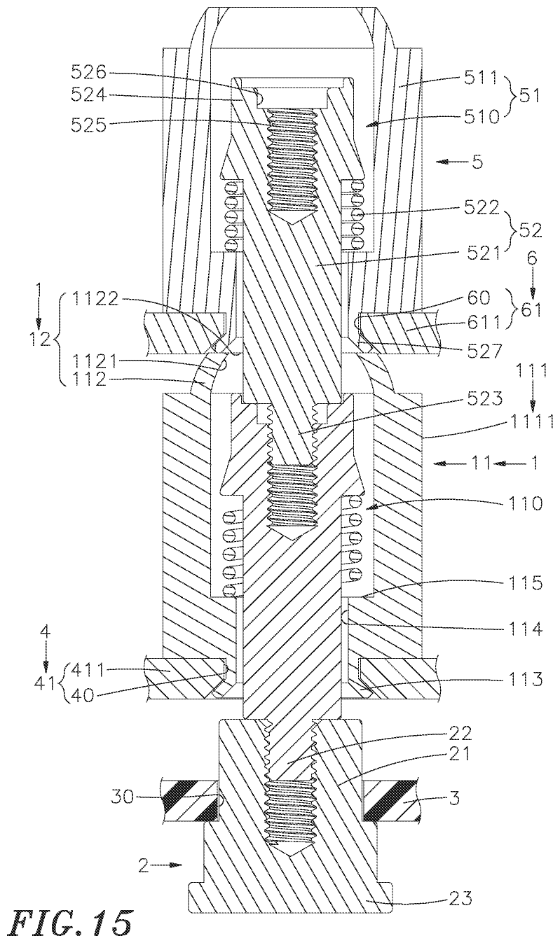

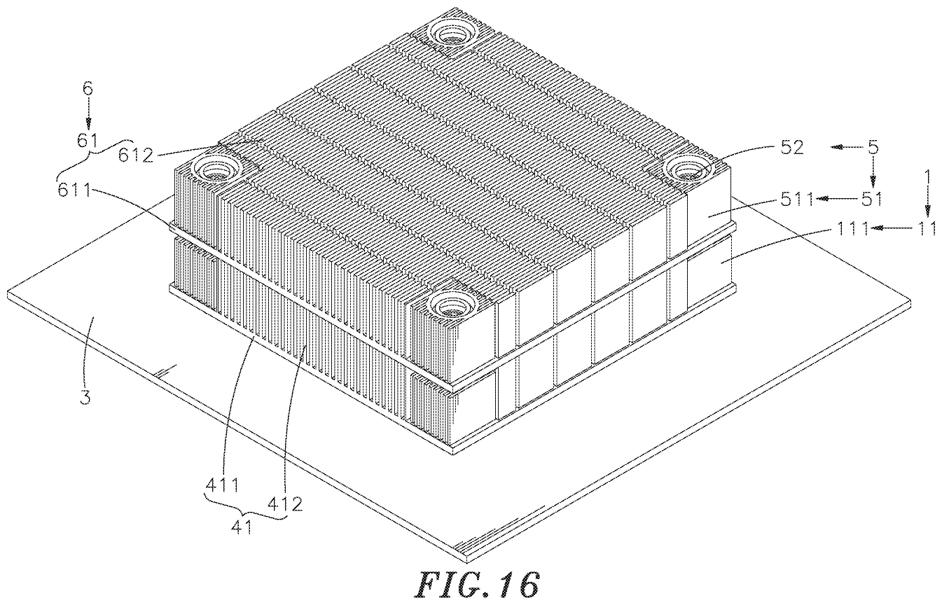

In addition, please refer to FIGS. 1 to 16 again. In the adjusting device 12 of the limiting mechanism 1 of the present invention, the operating part 124 on one side of the coupling member 121 can expose the outer side of the stopper 112 on one side of the accommodating space 110 of the sleeve 11. The operating part 124 comprises a docking unit 125 and an operating area 126, and the docking unit 125 of the operating part 124 is used for assembling at least a second positioning device. The said second positioning device comprises a second limiting mechanism 5 (please also refer to FIGS. 15 and 16). The said second limiting mechanism 5 comprises a second sleeve 51 and a second adjusting device 52 located inside the said second sleeve 51. The said second sleeve 51 is provided with a second accommodating space 510 for assembling the said second adjusting device 52 inside, and is also provided with a second non-planar heat dissipation portion 511 outside. The said second adjusting device 52 comprises a second coupling member 521 and a second elastic member 522 attached onto the said second coupling member 521. The said second coupling member 521 has a second connecting part 523 on one side and a second operating part 524 on the other side. The said second operating part 524 comprises a second docking unit 525 and a second operating area 526. The said second connecting part 523 on one side of the said second coupling member 521 is aligned and assembled at the docking unit 125 of the operating area 126 of the operating part 124. The said second sleeve 51 is provided with a second mounting portion 527 on one side that abuts the stopper 112, and the said second mounting portion 527 can be used to assemble at a third positioning hole 60 of a third board member 6.

In addition, in the coupling member 121 of the present invention, the operating area 126 of the operating part 124 and the said second operating area 526 of the said second operating part 524 of the said second coupling member 521 can be respectively in various shapes such as star-shaped groove, quadrangular groove, hexagonal groove or polygonal groove. The space between the outer stopper 112 on one side of the accommodating space 110 of the sleeve 11 and the said second mounting portion 527 of the said second sleeve 51 can be assembled in the third positioning hole 60 of the third board member 6. The second board member 4 can be a heat dissipation device 41 or a circuit board. The heat dissipation device 41 comprises a bottom plate 411 that resists the surface of a predetermined heating element 31 provided on the first board member 3, and a plurality of heat dissipation fins 412 formed on the surface of the bottom plate 411. The third board member 6 can also be a second heat dissipation device 61 or another circuit board, and the said second heat dissipation device 61 comprises a second bottom plate 611 that resists the second board member 4 and a second plurality of heat dissipation fins 612 formed on the surface of the said second bottom plate 611.

The above-mentioned docking portion 21 of the base 2 of the present invention can be assembled at the first positioning hole 30 of the first board member 3 by welding, inserting or riveting. The mounting portion 113 of the sleeve 11 of the limiting mechanism 1 can also be assembled at the second positioning hole 40 of the second board member 4 by welding, inserting or riveting. The said second mounting portion 527 of the said second sleeve 51 can also be assembled at the third positioning hole 60 of the third board member 6 by welding, inserting or riveting.

The limiting mechanism 1 of the above-mentioned positioning device of the present invention can be assembled on the base 2. The limiting mechanism 1 and base 2 of at least one positioning device can be used to assemble it at the second board member 4, the first board member 3 or the third board member 6. The heat energy generated by the predetermined heating element 31 on the first board member 3 during operation can be quickly dissipated through the second board member 4 or the third board member 6. At the same time, the heat dissipation portion 111 of the sleeve 11 of the limiting mechanism 1 can also be used to effectively increase the heat dissipation area to achieve the purpose of assisting the first board member 3, the second board member 4 or the third board member 6 for heat dissipation and cooling. It can also accelerate the rapid dissipation of heat energy generated by the predetermined heating element 31, the first board member 3, the second board member 4 or the third board member 6 during operation.

The above description is only preferred embodiments of the present invention and do not limit the patent scope of the present invention. Therefore, all simple modifications and equivalent structural changes made by using the description and drawings of the present invention shall be included in the patent scope of the present invention and shall be clearly stated.

In summary, the above-mentioned positioning device with heat dissipation effect of the present invention can indeed achieve its effect and purpose when used. Therefore, this invention is truly an invention with excellent practicality and meets the application requirements for an invention patent, so the application must be filed in accordance with the law. We hope that the review committee will approve this case as soon as possible to protect the inventor's hard work. If the review committee has any doubts, please feel free to send us a letter for instructions. The inventor will do our best to cooperate. We sincerely appreciate it.

What is claimed is:

1. A positioning device with heat dissipation effect, comprising a limiting mechanism, said limiting mechanism comprising a sleeve and an adjusting device located inside said sleeve, said sleeve comprising an accommodating space defined therein for assembling said adjusting device and a non-planar heat dissipation portion located on an outer side thereof, said adjusting device comprising a coupling member and an elastic member sleeved on said coupling member, said coupling member comprising a connecting part located on one side thereof and an operating part located on an opposite side thereof.

2. The positioning device with heat dissipation effect as claimed in claim 1, wherein said non-planar heat dissipation portion is selectively a plurality of fins formed on the outside of said sleeve in a two-phase symmetrical shape, a plurality of said fins formed on the outside of said sleeve in a cross-shaped symmetry, a plurality of said fins formed on the outside of said sleeve in a polygonal symmetry, a plurality of said fins formed on the outside of said sleeve in a spiral shape, or a plurality of radial said fins formed on the outside of said sleeve, and said sleeve is selectively made of aluminum, copper or alloy materials thereof, and the thermal conductivity of said sleeve is between 70˜500 W/m·k.

3. The positioning device with heat dissipation effect as claimed in claim 1, wherein said sleeve of said limiting mechanism comprises an inner cylinder and a heat dissipation cylinder covering the outside of said inner cylinder; said non-planar heat dissipation portion is selectively a plurality of said fins formed on the outside of said heat dissipation cylinder in a two-phase symmetrical shape, a plurality of said fins formed on the outside of said heat dissipation cylinder in a cross-shaped symmetry, a plurality of said fins formed on the outside of said heat dissipation cylinder in a polygonal symmetry, a plurality of said fins formed on the outside of said heat dissipation cylinder in a spiral shape, or a plurality of radial said fins formed on the outside of said heat dissipation cylinder; said inner cylinder and said heat dissipation cylinder is selectively made of aluminum, copper or alloy materials thereof, and the thermal conductivity of said inner cylinder and said heat dissipation cylinder is between 70˜500 W/m·k.

4. The positioning device with heat dissipation effect as claimed in claim 1, wherein said limiting mechanism further comprises a stopper on the outside of said accommodating space of said sleeve to limit said coupling member, so that said coupling member is movable vertically in said accommodating space, and said operating part on one side of said coupling member exposes said stopper; said coupling member comprises a flange portion protruding from the outside near said operating part to resist an inner surface of said stopper, a mounting portion located at an opposite outside of said accommodating space relative to said stopper for assembling a second board member, a through hole with a reduced diameter located on the side of said accommodating space near said mounting portion, and an inner shoulder formed at a position adjacent to said through hole and said accommodating space.

5. The positioning device with heat dissipation effect as claimed in claim 4, wherein said operating part on one side of said coupling member exposes the outer side of said stopper on one side of said accommodating space of said sleeve, said operating part comprising a docking unit and an operating area, and said docking unit of said operating part being used for assembling at least a second positioning device, the said second positioning device comprising a second limiting mechanism, the said second limiting mechanism comprising a second sleeve and a second adjusting device located inside the said second sleeve, the said second sleeve being provided with a second accommodating space for assembling the said second adjusting device inside, and being also provided with a second non-planar heat dissipation portion outside, the said second adjusting device comprising a second coupling member and a second elastic member attached onto the said second coupling member, the said second coupling member comprising a second connecting part on one side and a second operating part on an opposite side, the said second operating part comprising a second docking unit and a second operating area, the said second connecting part on one side of the said second coupling member being aligned and assembled at said docking unit of said operating area of said operating part, the said second sleeve comprising a second mounting portion on one side that abuts said stopper.

6. The positioning device with heat dissipation effect as claimed in claim 5, wherein said operating area of said operating part on one side of said coupling member and the said second operating area of the said second operating part of the said second coupling member are selectively in a star-shaped groove, a quadrangular groove, a hexagonal groove or a polygonal groove; the space between said outer stopper on one side of said accommodating space of said sleeve and the said second mounting portion of the said second sleeve is assembled with a third board member; the said third board member is selectively a second heat dissipation device or a circuit board, and the said second heat dissipation device of the said third board member comprising a second bottom plate that resists the said second board member and a plurality of heat dissipation fins formed on the surface of the said second bottom plate of the said second heat dissipation device of the said third board member.

7. The positioning device with heat dissipation effect as claimed in claim 5, wherein said limiting mechanism further comprises a base set at a bottom side of said sleeve, said base comprising a docking portion, a connecting portion on one side of said docking portion for said connecting part to be aligned and assembled at said connecting portion, and a chassis body on an opposite side of said docking part, said docking portion reducing the outer diameter and being formed on said chassis body, said connecting portion reducing the outer diameter being formed on the other side of said docking portion opposite said chassis body, said docking portion being used to assemble a first board member.

8. The positioning device with heat dissipation effect as claimed in claim 7, wherein the said second board member is a heat dissipation device, said heat dissipation device of the said second board member comprising a bottom plate resisting the surface of a predetermined heating element set on the said first board member and a plurality of said heat dissipation fins formed on the surface of said bottom plate.

9. The positioning device with heat dissipation effect as claimed in claim 7, wherein said connecting part on one side of said coupling member and said connecting portion on one side of said base are respectively and selectively a screw rod and a screw hole, a pin and a pin hole, or a tapered cylinder and a tapered hole.
